(19) United States
(12) Patent Application Publication
(10) Pub. No.: US 2006/0139110 A1
(43) Pub. Date: Jun. 29, 2006

(54) Method to compensate the VCO buffer Q factor at low frequency band

(76) Inventor: Qiang Li, Irvine, CA (US)

Correspondence Address: CHRISTIE, PARKER & HALE, LLP, PO BOX 7068, PASADENA, CA, 91109-7068, US

(21) Appl. No.: 11/055,127

(22) Filed: Feb. 9, 2005

Related U.S. Application Data
(60) Provisional application No. 60/636,506, filed on Dec. 14, 2004.

(51) Int. Cl. H03B 5/12

(52) U.S. Cl. 331/36 C

(57) ABSTRACT

A voltage control oscillator (VCO) buffer for a local oscillator (LO) generator system of a phase locked loop (PLL) in a transceiver chip. The VCO buffer includes a capacitor bank, a VCO buffer core and a current stirring unit. The VCO buffer core receives an input signal, and outputs an output signal. The input signal and the output signal have substantially the same frequency. A capacitance of the capacitor bank and a magnitude of a current supplied by the current stirring unit are variable depending on a frequency of the input signal.

### CROSS-REFERENCE TO RELATED APPLICATIONS

This application claims priority to and the benefit of U.S. Provisional Patent Application No. 60/636,506 entitled “Method to Compensate the VCO Buffer Q Factor at Low Frequency Band” filed on Dec. 14, 2004, the entire content of which is incorporated by reference herein.

### FIELD OF THE INVENTION

The present invention relates to a local oscillator (LO) generator system for a phase locked loop (PLL) in a high frequency transceiver, and more particularly, to a method of compensating the Q factor of a voltage controlled oscillator (VCO) buffer at a low frequency band of the frequency range.

### BACKGROUND

A quad-band Global System for Mobile Communication/General Packet Radio Services (GSM/GPRS) RF transceiver supports relatively high and diverse carrier frequencies of 800 MHz, 900 MHz, 1800 MHz and 1900 MHz used in different regions of the world. A VCO of a PLL in such a transceiver correspondingly has a wide frequency range (e.g., from 3 GHz to 4 GHz). LC tuning using an LC tank circuit is typically used in both the VCO and the VCO buffer to cover such a wide frequency range. As the frequency goes down, more capacitance is added. This has a de-Q-ing effect to the output tank of both the VCO and the VCO buffer. As a result, the output swing at lower band is typically lower than the output swing at higher band. This could cause failure of the dividers that receive the VCO buffer output as an input.

Therefore, it is desirable to provide a method of compensating for the low voltage swing of the output signal in the low frequency band.

### SUMMARY

In an exemplary embodiment according to the present invention, a VCO buffer for an LO generator system is provided. The VCO buffer includes a VCO buffer core, a capacitor bank and a current stirring unit. The VCO buffer core receives an input signal having a frequency and outputs an output signal. The capacitor bank is coupled to the VCO buffer core, and has a capacitance which is variable. The current stirring unit is coupled to the VCO buffer core, and provides a current to the VCO buffer core. The capacitance of the capacitor bank and a magnitude of the current provided by the current stirring unit are variable depending on the frequency of the input signal.

In another exemplary embodiment according to the present invention, an LO generator system includes a VCO, a VCO buffer and at least one divider. The VCO receives a control signal and generates an oscillation signal having a frequency which depends on the control signal. The VCO buffer includes a VCO buffer core, a capacitor bank and a current stirring unit. The VCO buffer core receives the oscillation signal as an input signal and outputs an output signal. The capacitor bank is coupled to the VCO buffer core, and has a capacitance which is variable. The current stirring unit is coupled to the VCO buffer core, and provides a current to the VCO buffer core. The capacitance of the capacitor bank and a magnitude of the current provided by the current stirring unit are variable depending on the frequency of the input signal. The at least one divider receives the output signal, and generates a divided output signal.

In yet another exemplary embodiment according to the present invention, in a VCO buffer of an LO generator system, the VCO buffer for receiving an input signal and for outputting an output signal, and having a buffer core, a capacitor bank and a current stirring unit, a method of compensating for de-Q-ing at a low frequency band is provided. The method includes increasing a magnitude of a current provided by the current stirring unit as a frequency of the input signal to the VCO buffer decreases; and decreasing the magnitude of the current provided by the current stirring unit as the frequency of the input signal to the VCO buffer increases.

These and other aspects of the invention will be more readily comprehended in view of the discussion herein and accompanying drawings.

### BRIEF DESCRIPTION OF THE DRAWINGS

FIG. 1 is a block diagram of a local oscillator (LO) generator system in an exemplary embodiment according to the present invention;

FIG. 2 is a block diagram of a VCO buffer in the LO generator system of FIG. 1;

FIG. 3 is a simplified schematic diagram of a VCO buffer in another exemplary embodiment according to the present invention;

FIG. 4 is a graph showing a typical VCO buffer swing over an input frequency range of a previously used VCO buffer;

FIG. 5 is a graph showing a typical VCO buffer swing over an input frequency range in the VCO buffer of FIG. 3;

FIG. 6 is a graph showing a typical divided-by-four output of a ¼ divider coupled to a previously used VCO buffer; and

FIG. 7 is a graph showing a typical divided-by-four output of a ¼ divider coupled to the VCO buffer of FIG. 3.

### DETAILED DESCRIPTION

The small output swing at the low band caused by additional capacitors, i.e., increased capacitance in the LC tank circuit, can be compensated by increasing the amount of current provided to the VCO buffer core. However, if a conventional current supply is used to uniformly increase the supplied current over the frequency range of operation, the voltage swing near the high end of the frequency range may become too large, and the output signal may saturate or over-saturate at the high end of the frequency range.

In exemplary embodiments according to the present invention, a current stirring unit is added to a VCO buffer, and a band tuning signal or a tuning control signal is used to stir the current, such that the current is pumped up gradually as frequency goes lower. This way, lower swing of the output signals at the low frequency band is effectively compensated without saturating the output signals at the high frequency band.

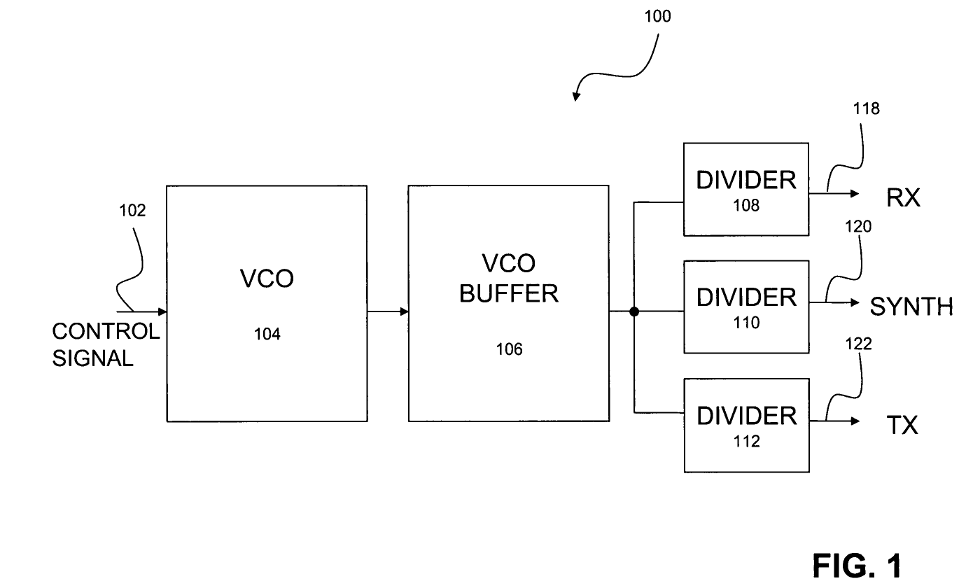

Referring now to FIG. 1, an LO generator system 100 includes a VCO 104, a VCO buffer 106, and a plurality of dividers 108, 110 and 112. The dividers 108, 110 and 112 may be ½ dividers, ¼ dividers or any combination thereof. The LO generator system 100, for example, may be a part of a phase locked loop (PLL) used in a transceiver, such as, for example, a quad-band GSM/GPRS RF transceiver that should operate over a wide range of frequencies (e.g., from 3 GHz to 4 GHz).

The VCO 104 receives a control signal (or a control voltage) 102, which is used to adjust the frequency of its output. The output of the VCO 104 is buffered by the VCO buffer 106 to drive subsequent devices. The output of the VCO buffer 106 is provided to the dividers 108, 110 and 112 to be frequency divided and output as a receive (RX) frequency signal 118, a synthesize frequency signal 120 and a transmit frequency signal 122, respectively.

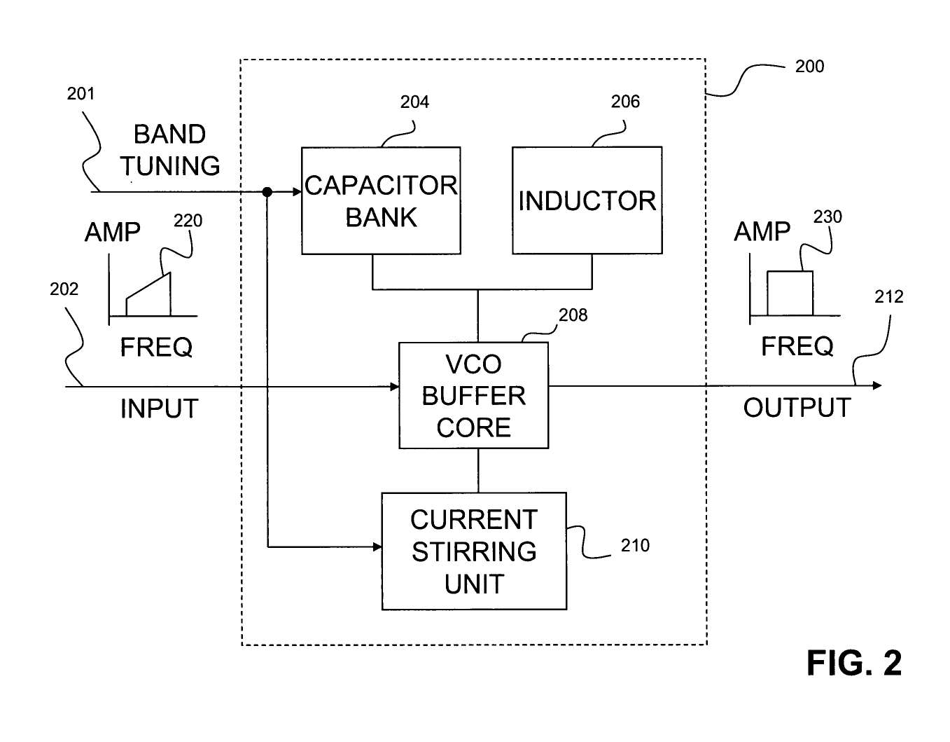

As shown in FIG. 2, a VCO buffer 200 includes a capacitor bank 204, an inductor 206, a VCO buffer core 208 and a current stirring unit 210. The VCO buffer 200, for example, may be used as the VCO buffer 106 of FIG. 1. A band tuning signal 201 is provided to both the capacitor bank 204 and the current stirring unit 210. The band tuning signal 201 includes a plurality of binary bits that can be referred to as band tuning bits or tuning control bits. The band tuning bits change states depending on the frequency of an input signal 202 applied to the VCO buffer core 208.

By way of example, the band tuning bits may include four bits B[0:3] or B<0>, B<1>, B<2> and B<3>. Further, these four bits may range from high to low (e.g., “1111” to “0000”) as the frequency increases from a relatively low frequency to a relatively high frequency over the frequency range of operation (e.g., 3 GHz to 4 GHz). In other embodiments, the band tuning bits may include more than four bits, such as, for example, B[0:4]. By increasing the number of bits, more precise tuning can be realized over the frequency range of interest.

As shown in FIG. 2, for example, the input signal 202 applied to the VCO buffer core 208 may have a non-flat level 220 in which the amplitude of the signal increases as the frequency of the input signal 202 increases. Due to the correction effected by the variable current provided by the current stirring unit 210, the output signal 212 may have a substantially flat output waveform 230 having a substantially constant level or amplitude over the frequency range as shown in FIG. 2. The correction, for example, can include applying higher gain at a lower frequency than at a higher frequency.

The capacitor bank 204 includes one or more capacitors that are always electrically coupled to the inductor 206 to form an LC tank circuit. The capacitor bank 204 also includes one or more capacitors that are electrically coupled to the inductor 206 in accordance with the states of the band tuning bits of the band tuning signal 201. These capacitors are used to adjust the capacitance of the capacitor bank 204 such that higher capacitance is provided at the lower end of the frequency range than at the higher end. This added capacitance results in a de-Q-ing effect and therefore lower Q and lower voltage swing. The current stirring unit 210 provides an increased current at the low end of the frequency range to counter the de-Q-ing effect.

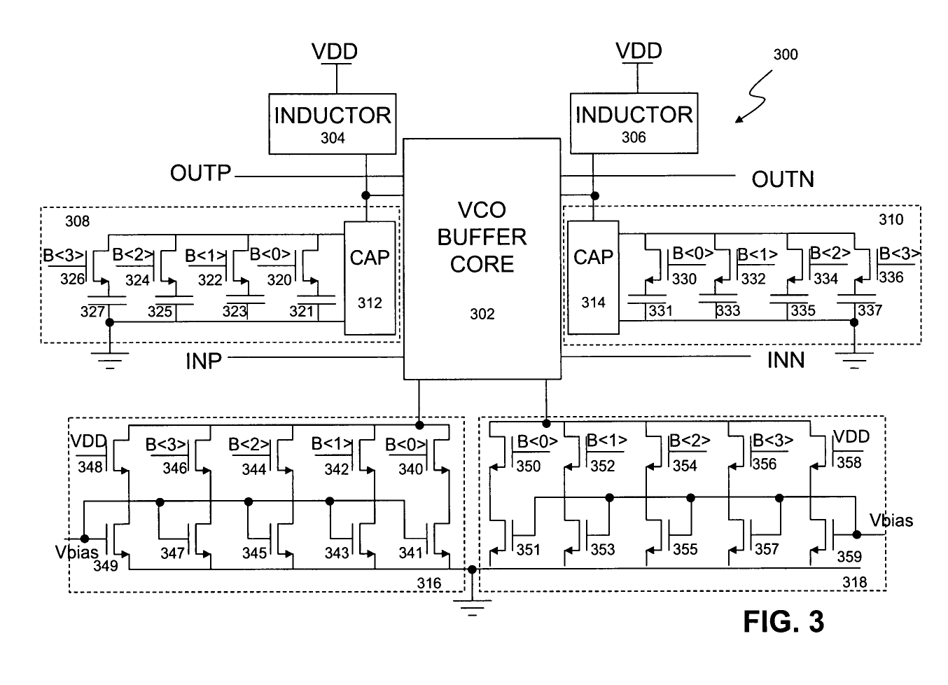

In practice, the signals outputted by the VCO are often differential signals. Therefore, as shown in FIG. 3, a VCO buffer 300 in another exemplary embodiment according to the present invention has a pair of differential input signals INP and INN and a pair of differential output signals OUTP and OUTN. The VCO buffer 300 can be used as the VCO buffer 106 in the LO generator system 100 of FIG. 1 provided that the input and output frequency signals applied and received in the LO generator system 100 are differential signals. The VCO buffer 300 as well as a VCO and dividers that are coupled to the VCO buffer 300 can be implemented on a single integrated circuit (IC) chip using CMOS technology. This way, the VCO buffer and/or other LO generator system components can be integrated with other CMOS devices on a single IC chip.

The VCO buffer 300 includes a VCO buffer core 302, inductors 304, 306, capacitor banks 308, 310 and current stirring units 316, 318. The inductors 304, 306 and the capacitor banks 308, 310 are coupled, respectively, to the output signals OUTP and OUTN of the VCO buffer core 302. This way, the inductor 304 and the capacitor bank 308 form an LC tank circuit for driving the output signal OUTP, and the inductor 306 and the capacitor bank 310 form an LC tank circuit for driving the output signal OUTN.

The inductors 304 and 306 are coupled between the voltage source VDD and the capacitor banks 308 and 310, respectively. The capacitor bank 308 includes a capacitor 312 that is always electrically coupled between the inductor 304 and ground. The capacitor bank 308 also includes capacitors 321, 323, 325 and 327, each of which has a first electrode coupled to ground and a second electrode coupled to the inductor 304 via transistors 320, 322, 324 and 326, respectively. The transistors 320, 322, 324 and 326 receive at their respective control electrodes or gates, band tuning bits B<0>, B<1>, B<2> and B<3> of the band tuning signal B[0:3].

Similarly, the capacitor bank 310 includes a capacitor 314 that is always electrically coupled between the inductor 306 and ground. The capacitor bank 310 also includes capacitors 331, 333, 335 and 337, each of which has a first electrode coupled to ground and a second electrode coupled to the inductor 306 via transistors 330, 332, 334 and 336, respectively. The transistors 330, 332, 334 and 336 receive at their respective control electrodes or gates, the band tuning bits B<0>, B<1>, B<2>and B<3>of the band tuning signal B[0:3].

The transistors in the capacitor banks 308 and 310 shown in FIG. 3 are N-channel CMOS transistors. In other embodiments, any suitable switches or transistors can be used instead. Further, the capacitors 321, 323, 325 and 327 of the capacitor bank 308 may have the same or different capacitances with each other, and the capacitors 331, 333, 335 and 337 of the capacitor bank 310 may have the same or different capacitance with each other.

As the frequency of the input signals INP and INN decreases, the capacitance of the capacitor banks 308 and 310 increases. On the other hand, as the frequency of the input signals INP and INN increases, the capacitance of the capacitor banks 308 and 310 decreases. By way of example, the band tuning bits B[0:3] may change from “1111” to “0000” as the frequency of the input signals changes from the low end to the high end of the frequency range.

When some of the band tuning bits B[0:3] are “1” while other ones of the band tuning bits B[0:3] are “0”, the transistors that are coupled to the band tuning bits having the value of “1” are turned on and the transistors that are coupled to the band tuning bits having the value of “0” are turned off. Therefore, the capacitance of the capacitor banks 308 and 310 are between the capacitance when the band tuning bits are “1111” and the capacitance when the band tuning bits are “0000”.

When the band tuning bits B[0:3] of “1111” are applied to the capacitor banks 308 and 310, all of the transistors 320, 322, 324, 326, 330, 332, 334 and 336 are turned on. Therefore, the capacitors 321, 323, 325 and 327 are electrically coupled in parallel with the capacitor 312, and the capacitors 331, 333, 335 and 337 are electrically coupled in parallel with the capacitor 314. With such increase in the capacitance at the lower band, the output signal is de-Q'd, resulting in a lower Q. Such low Q tends to result in a low voltage swing of the output signals OUTP and OUTN.

To overcome the low voltage swing caused by the d-Q-ing due to additional capacitance added near the low end of the frequency range, the VCO buffer 300 includes a pair of current stirring units 316 and 318, one for each of the positive and negative output signals OUTP and OUTN.

The current stirring unit 316 includes five (5) pairs of N-channel transistors that are coupled between the VCO buffer core 302 and ground. A first pair of transistors includes a transistor 348 whose drain is coupled to the VCO buffer core 302, and a gate is coupled to the voltage source VDD. Since the gate of the transistor 348 is coupled to VDD, the transistor 348 is turned on during normal operation as long as the VDD provides a suitable voltage. A source of the transistor 348 is coupled to a drain of a transistor 349 of the first pair of transistors. The source of the transistor 349 is coupled to ground.

Second, third, fourth and fifth pairs of transistors respectively include transistors 340, 342, 344 and 346 whose drains are coupled to the VCO buffer core 302, and gates are respectively coupled to the band tuning bits B<0>, B<1>, B<2> and B<3>. Sources of the transistors 340, 342, 344 and 346 are respectively coupled to drains of transistors 341, 343, 345 and 347, respectively, of the second, third, fourth and fifth pairs of transistors. The sources of the transistors 341, 343, 345 and 347 are coupled to ground. Gates of the transistors 341, 343, 345, 347 and 349 receive a bias voltage Vbias, and therefore, the transistors 341, 343, 345, 347 and 349 are turned on during normal operation, as long as Vbias has a suitable voltage level and the band tuning bits B<0>, B<1>, B<2> and B<3> are “1111”.

The current stirring unit 318 includes five (5) pairs of N-channel transistors that are coupled between the VCO buffer core 302 and ground. The first pair includes transistors 358 and 359, wherein a gate of the transistor 358 is coupled to a voltage source VDD, and a gate of the transistor 359 is coupled to a bias voltage Vbias. The second to fourth pairs of transistors include transistors 350 and 351, transistors 352 and 353, transistors 354 and 355, and transistors 356 and 357, respectively. Gates of the transistors 350, 352, 354 and 356 are coupled to the band tuning bits B<0>, B<1>, B<2> and B<3>, respectively, while gates of the transistors 351, 353, 355, 357 and 359 are coupled to the bias voltage Vbias. Since the current stirring unit 318 operates in substantially the same manner as the current stirring unit 316, only the current stirring unit 316 will be described in detail below.

Referring now to the current stirring unit 316, unlike the first pair of transistors 348 and 349 that continuously supplies current during the normal operation, the second pair of transistors 340 and 341, the third pair of transistors 342 and 343, the fourth pair of transistors 344 and 345, and the fifth pair of transistors 346 and 347 supply current depending on the states of the band tuning bits B<0>, B<1>, B<2> and B<3>. By way of example, when the band tuning bits B[0:3] are “1111” (i.e., low frequency), all four of the transistors 340, 342, 344 and 346 are turned on. This way, additional current is provided at the low end (e.g., 3 GHz) of the frequency range to counter the de-Q-ing effect of increasing capacitance of the LC tank circuit. On the other hand, when the band tuning bits B[0:3] are “0000” (i.e., high frequency), all four of the transistors 340, 342, 344 and 346 are turned off such that only the first pair of transistors 348 and 349 provides the current. This way, the possibility of saturation or over-saturation at the high end (e.g., 4 GHz) of the frequency range is reduced or eliminated.

When some of the band tuning bits B[0:3] are “1” while other ones of the band tuning bits B[0:3] are “0”, the transistors that are coupled to the band tuning bits having the value of “1” are turned on and the transistors that are coupled to the band tuning bits having the value of “0” are turned off. Therefore, the magnitude of the current provided by the current stirring unit 316 is between the magnitude of the current when the band tuning bits are “1111” and the magnitude of the current when the band tuning bits are “0000”.

It should be noted that the W/L ratio of the transistors 340-349 in the current stirring unit 316 and the transistors 350-359 in the current stirring unit 318 may be the same or different from each other to vary the amount of currents using different weights in each transistor. Further, the W/L ratio of each pair of transistors may be the same as each other, while the W/L ratio of the transistors in different pairs of transistors may be different from each other.

While five pairs of transistors are used in each of the current stirring units 316 and 318 of the described exemplary embodiment, the pairs of transistors used in other embodiments may be different. By way of example, five (5) band tuning bits may be applied to five (5) pairs of transistors in current stirring units each having six (6) pairs of transistors, where one of the pairs is applied the voltage source VDD at the gate of one of its transistors.

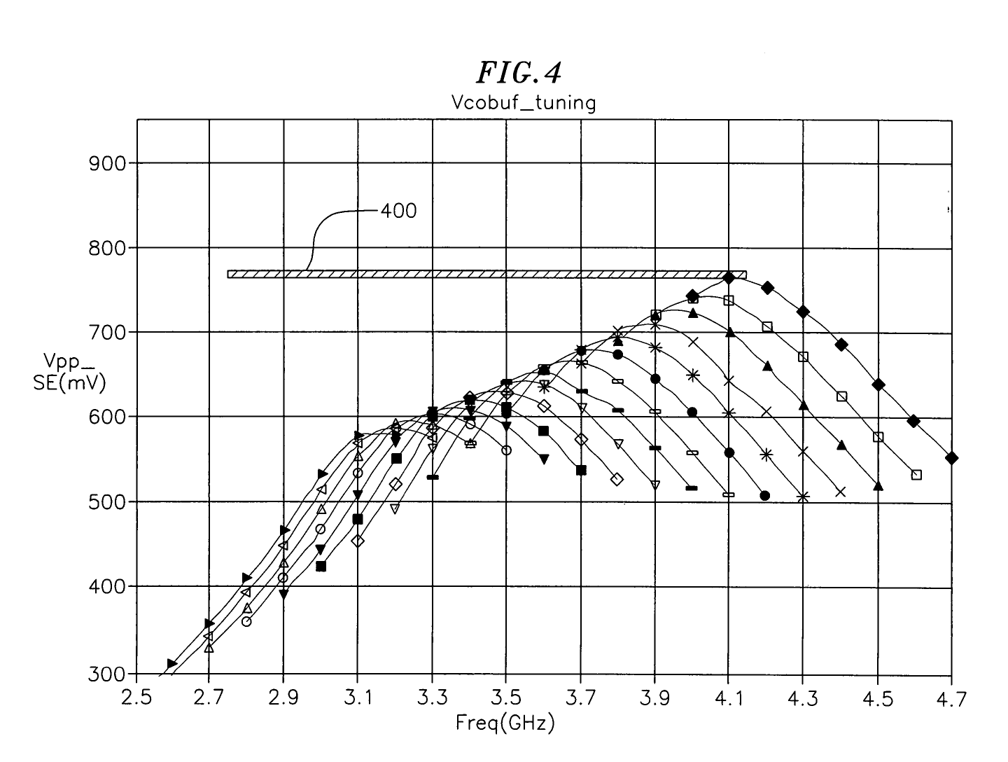

Referring now to FIG. 4, it can be seen that a typical peak-to-peak voltage of the output signals is lower at the lower end of the frequency range in a previously used VCO buffer. For example, while a typical peak-to-peak voltage of the output signals corresponding to the input frequency of 4.1 GHz can be more than 750 mV as shown in FIG. 4, a typical peak-to-peak voltage of the output signals corresponding to the input frequency of 2.9 GHz is less than 500 mV because of the de-Q-ing effect of additional capacitance in the LC tank circuit.

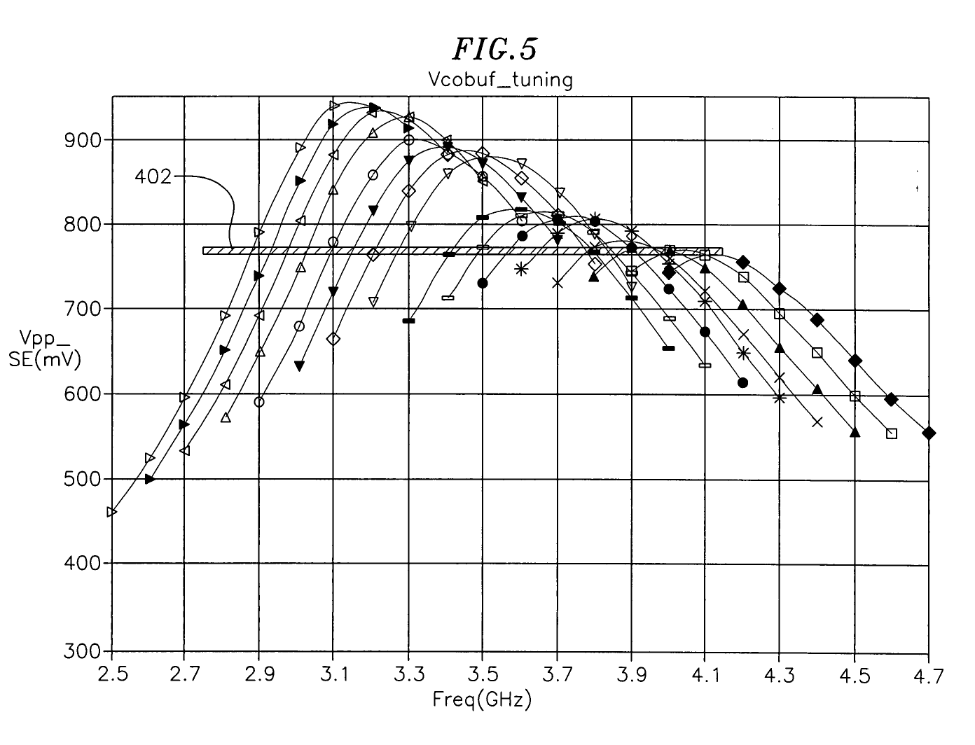

As can be seen in FIG. 5, the current stirring units 316 and 318 of the present invention increase the voltage swing of the output voltage at the low end of the frequency range. For example, a typical peak-to-peak voltage at 2.9 GHz is now at least 600 mV and as high as 800 mV as shown in FIG. 5. On the other hand, the maximum typical peak-to-peak voltage at 4.1 is at substantially the same level as that of FIG. 4. This perhaps can best be seen by comparing the voltage levels with respect to the bar 400 of FIG. 4 and the bar 402 of FIG. 5. The bars 400 and 402 are located at substantially the same voltage level, and provide a good reference point when comparing the graphs of FIGS. 4 and 5.

By making the peak-to-peak voltage of the VCO buffer output signal to be generally higher at the low frequency band than at the high frequency band, the non-flat characteristic of the input signal (which is the VCO output signal, e.g., see 220 of FIG. 2) over the frequency range can be corrected such that the output signal of the VCO buffer 300 has a generally flat characteristic over the frequency range (e.g., see 230 of FIG. 2).

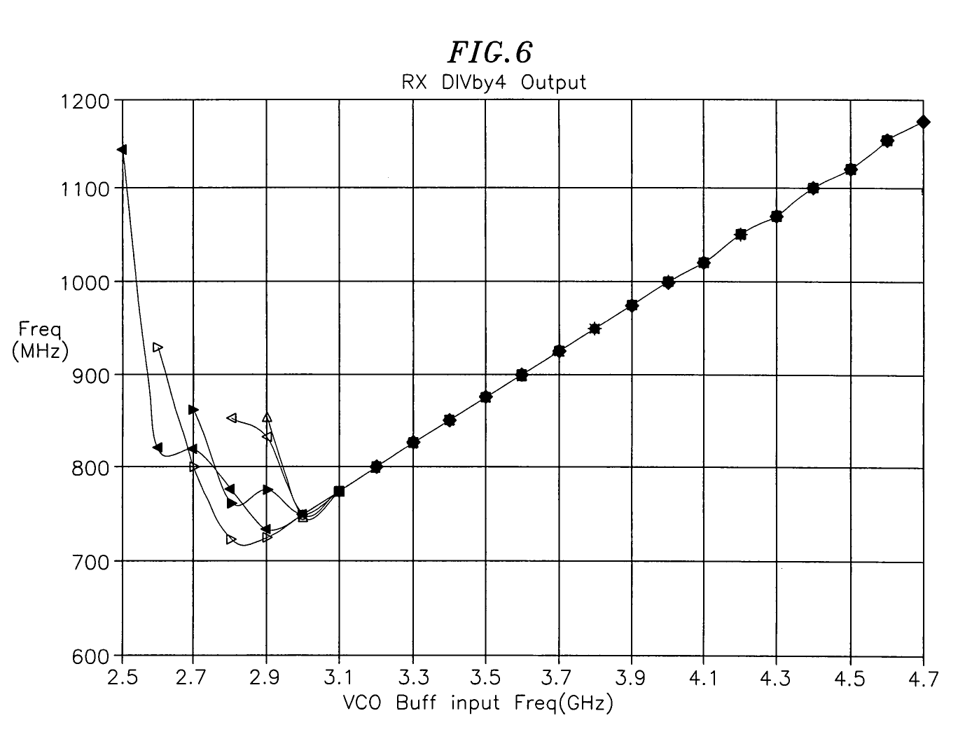

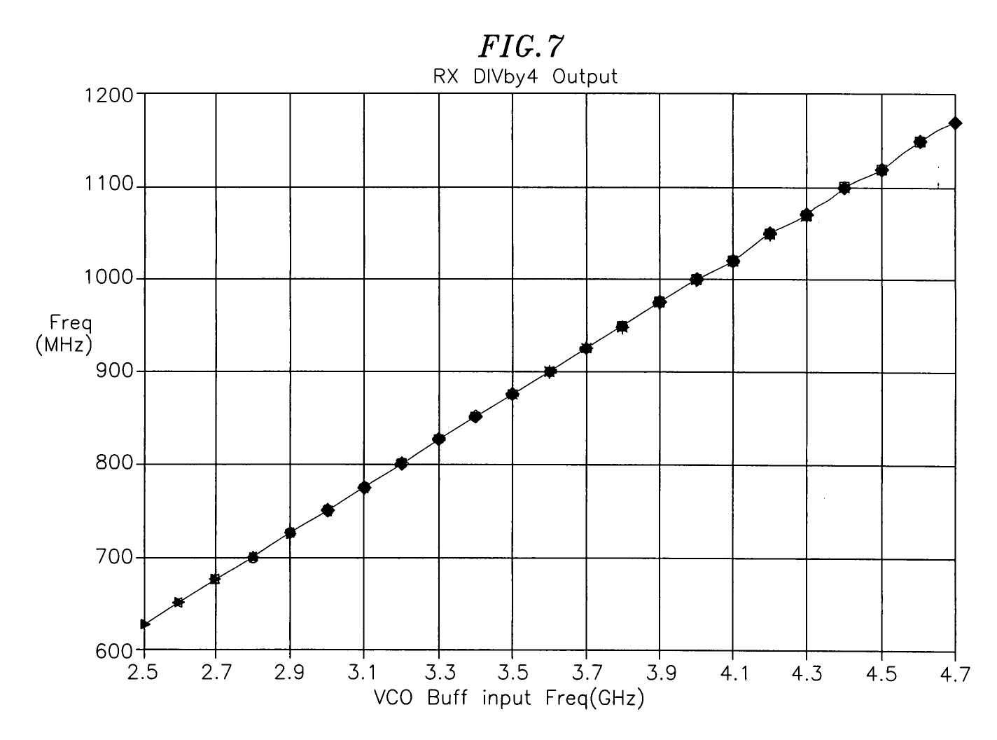

The effect of the described embodiments of the present invention can also be seen when comparing FIGS. 6 and 7 together. FIG. 6 is a graph showing an output of an RX frequency signal at the output of a ¼ divider coupled to a previously used VCO buffer. It can be seen that the output does not demonstrate good linear characteristics at a low end of the input frequency range, for example, near 2.9 GHz. In contrast, as can be seen in FIG. 7, the RX frequency signal at the output of a ¼ divider coupled to the VCO buffer of the present invention shows a substantially linear characteristics over the frequency range of 2.5 GHz to 4.7 GHz.

While certain exemplary embodiments have been described above in detail and shown in the accompanying drawings, it is to be understood that such embodiments are merely illustrative of and not restrictive of the broad invention. It will thus be recognized that various modifications may be made to the illustrated and other embodiments of the invention described above, without departing from the broad inventive scope thereof. In view of the above it will be understood that the invention is not limited to the particular embodiments or arrangements disclosed, but is rather intended to cover any changes, adaptations or modifications which are within the spirit and scope of the present invention as defined by the appended claims and equivalents thereof.

I Claim:

1. A voltage controlled oscillator (VCO) buffer for a local oscillator (LO) generator system, the VCO buffer comprising:
a VCO buffer core for receiving an input signal having a frequency and for outputting an output signal;
a capacitor bank coupled to the VCO buffer core, the capacitor bank having a capacitance which is variable; and
a current stirring unit coupled to the VCO buffer core, and for providing a current to the VCO buffer core,
wherein the capacitance of the capacitor bank and a magnitude of the current provided by the current stirring unit are variable depending on the frequency of the input signal.

2. The VCO buffer of claim 1, wherein the capacitance of the capacitor bank increases and the magnitude of the current provided by the current stirring unit increases as the frequency of the input signal decreases.

3. The VCO buffer of claim 1, wherein the capacitance of the capacitor bank decreases and the magnitude of the current provided by the current stirring unit decreases as the frequency of the input signal increases.

4. The VCO buffer of claim 1, wherein an amplitude of the input signal increases as the frequency of the input signal increases, and wherein the VCO buffer maintains a substantially constant amplitude for the output signal by applying higher gain at a lower frequency than at a higher frequency.

5. The VCO buffer of claim 1, wherein each of the input signal and the output signal includes a pair of differential signals.

6. The VCO buffer of claim 1, wherein a tuning control signal comprising a plurality of binary bits is applied to the capacitor bank and the current stirring unit to control the capacitance of the capacitor bank and the magnitude of the current provided by the current stirring unit.

7. The VCO buffer of claim 6, wherein states of the binary bits change as the frequency of the input signal is changed such that the states of the binary bits are indicative of the frequency of the input signal.

8. The VCO buffer of claim 1, further comprising an inductor coupled to the capacitor bank to form an LC tank circuit coupled to the VCO buffer core.

9. The VCO buffer of claim 1, wherein the input signal and the output signal have substantially the same frequency.

10. A local oscillator (LO) generator system comprising:
a voltage controlled oscillator (VCO) for receiving a control signal and for generating an oscillation signal having a frequency which depends on the control signal;
a VCO buffer comprising:
a VCO buffer core for receiving the oscillation signal as an input signal and for outputting an output signal;
a capacitor bank coupled to the VCO buffer core, the capacitor bank having a capacitance which is variable; and
a current stirring unit coupled to the VCO buffer core, and for providing a current to the VCO buffer core,
wherein the capacitance of the capacitor bank and a magnitude of the current provided by the current stirring unit are variable depending on the frequency of the input signal; and
at least one divider for receiving the output signal, and for generating a divided output signal.

11. The LO generator system of claim 10, wherein the capacitance of the capacitor bank increases and the magnitude of the current provided by the current stirring unit increases as the frequency of the input signal decreases.

12. The LO generator system of claim 10, wherein the capacitance of the capacitor bank decreases and the magnitude of the current provided by the current stirring unit decreases as the frequency of the input signal increases.

13. The LO generator system of claim 10, wherein an amplitude of the input signal increases as the frequency of the input signal increases, and wherein the VCO buffer maintains a substantially constant amplitude for the output signal by applying higher gain at a lower frequency than at a higher frequency.

14. The LO generator system of claim 10, wherein each of the input signal and the output signal includes a pair of differential signals.

15. The LO generator system of claim 10, wherein a tuning control signal comprising a plurality of binary bits is applied to the capacitor bank and the current stirring unit to control the capacitance of the capacitor bank and the magnitude of the current provided by the current stirring unit.

16. The LO generator system of claim 15, wherein states of the binary bits change as the frequency of the input signal is changed such that the states of the binary bits are indicative of the frequency of the input signal.

17. In a voltage controlled oscillator (VCO) buffer of a local oscillator (LO) generator system, the VCO buffer for receiving an input signal and for outputting an output signal, and having a buffer core, a capacitor bank and a current stirring unit, a method of compensating for de-Q-ing at a low frequency band comprising:
increasing a magnitude of a current provided by the current stirring unit as a frequency of the input signal to the VCO buffer decreases; and
decreasing the magnitude of the current provided by the current stirring unit as the frequency of the input signal to the VCO buffer increases.

18. The method of claim 17, wherein a capacitance of the capacitor bank increases as the frequency of the input signal decreases, and the capacitance of the capacitor bank decreases as the frequency of the input signal increases.

19. The method of claim 18, wherein a tuning control signal comprising a plurality of binary bits are provided to the capacitor bank and the current stirring unit to control the capacitance of the capacitor bank and the magnitude of the current provided by the current stirring unit.

20. The method of claim 17, wherein each of the input signal and the output signal comprises a pair of differential signals.
